(19) United States
(12) Patent Application Publication
(10) Pub. No.: US 2019/0322563 A1
(43) Pub. Date: Oct. 24, 2019

(54) APPARATUS AND METHODS FOR PRODUCING GLASS COMPRISING CRYSTAL ZIRCONIA

(71) Applicant: CORNING INCORPORATED, CORNING, NY (US)

(72) Inventors: Dana Craig Bookbinder, Corning, NY (US); Timothy Michael Gross, Corning, NY (US); Joseph James Mclntosh, Painted Post, NY (US)

(21) Appl. No.: 16/475,502

(22) PCT Filed: Jan. 3, 2018
(86) PCT No.: PCT/US2018/012139

§ 371 Date: Jul. 2, 2019

Related U.S. Application Data
(60) Provisional application No. 62/441,772, filed on Jan. 3, 2017.

(51) Int. Cl. C03B 5/43; C03B 17/06; C03B 5/167; C04B 35/486; C30B 11/00; C30B 29/16

(52) U.S. Cl. CPC C03B 5/43; C03B 17/06; C03B 5/1672; C04B 35/486; C30B 11/002; C30B 11/003; C04B 2235/765; C04B 2235/3203; C04B 2235/3206; C04B 2235/3208; C04B 2235/3225; C04B 2235/725; C04B 2235/762; C30B 29/16

(57) ABSTRACT

Apparatus and methods used in the manufacture of glass articles, the apparatus and methods including a surface of crystal zirconia are disclosed. Methods of making glass articles utilizing the apparatus and methods of manufacturing the apparatus are also disclosed.

### CROSS-REFERENCE TO RELATED APPLICATION

This application claims the benefit of priority under 35 U.S.C. § 119 of U.S. Provisional Application Ser. No. 62/441,772 filed on Jan. 3, 2017, the content of which is relied upon and incorporated herein by reference in its entirety.

### FIELD

Embodiments of the disclosure generally relate to apparatus and methods for the manufacture of glass, glass articles and refractory materials used in these apparatus and methods, the apparatus and methods comprising crystal zirconia.

### BACKGROUND

Glass manufacturing apparatus, systems and methods are utilized in a wide variety of fields, and molten glass is produced and moved through such apparatus systems and formed into various glass parts, for example glass sheets, glass containers and other glass parts.

In the manufacture of glass sheets, historically, display quality glass sheets have been commercially produced using the float process or the fusion overflow downdraw process (fusion process). In each case, the process involves three basic steps: melting batch materials in a tank (also call glass melters or melters), conditioning the molten glass to remove gaseous inclusions and to homogenize the molten glass in preparation for forming, and forming, which in the case of the float process involves the use of a molten tin bath, while for the fusion process, involves the use of a forming structure, e.g., an isopipe. In each case, the forming step produces a ribbon of glass which is separated into individual glass sheets. The sheets are inspected and those that meet the customer's requirements are finished and delivered. The sheets that fail to pass inspection and have a low number of inclusions (e.g., particles of ZrO₂, Pt) are normally crushed into cullet and remelted with new raw materials. The sheets that have a high number of inclusions are discarded, leading to higher manufacturing costs.

A goal for both the float and fusion processes is to produce glass sheets having low levels of defects, i.e., low levels of gaseous and solid defects. More particularly, the goal is to achieve a low level of defects for the glass sheets as manufactured to reduce the number of sheets that are rejected by the inspection process. The economics of the process and thus the cost of the glass sheets are dependent on level of rejected glass.

Gaseous defects are introduced into the molten glass during the melting process, as well as downstream through such mechanisms as hydrogen permeation (see Dorfeld et al., U.S. Pat. No. 5,785,726). Solid defects can originate from the batch materials, as well as from the refractories and/or heat-resistant metals that come into contact with the molten glass in the tank as it moves through the process. Wear of the glass-engaging surfaces of the system, including the furnace used to melt the batch materials is one of the primary sources of solid defects. A common material for the walls of a glass melting systems and apparatus such as the melting furnace is glass-bonded polycrystalline zirconia made from powder or grains, e.g., electrocast zirconia, where the zirconia powder or grains have a cross-sectional dimensional in the range of 1-80 microns. The resultant fused cast material is a combination of small zirconia crystals (typically monoclinic or tetragonal in structure within a glassy phase). The glassy phase component of such refractories generally exceeds 5%. When the glassy phase erodes from the material as a result of furnace wear, for example, it causes the formation of zirconia-containing solid defects in the molten glass, thus this has been and continues to be a challenging problem in the manufacture of display quality glass sheets.

As the demand for products employing display quality glass sheets has increased, manufacturers of such products have sought glass sheets of ever larger dimensions in order to achieve economies of scale. For example, the current sheets supplied to manufacturers of flat panel displays are known as Gen 10 sheets and have dimensions of 3200 mm×3000 mm×0.7 mm. From the point of view of glass manufacturers, the production of larger display quality glass sheets means that more glass has to be moved through the manufacturing process per unit time. However, this increase in production rate cannot be achieved through compromises in the quality of the sheets supplied to the customer. Indeed, as the resolution of display products has and continues to increase, the quality of the glass sheets used in such products has and must continue to improve. In terms of rejected glass sheets, larger sheets make reducing the levels of solid and gaseous defects even more important because each rejected sheet represents more glass that was produced but not supplied to a customer. The higher quality standards demanded by customers only exacerbates this problem.

One of the limiting steps in the production of high quality glass sheets is glass melting and the subsequent fining (refining) of the molten glass to remove gaseous inclusions. In the past, melting has been accomplished through a combination of burning fossil fuels (e.g., methane) and direct electrical heating (Joule heating). The Joule heating has been performed using tin oxide electrodes. These electrodes have set an upper limit on the production rate of display quality glass sheets. In particular, for melters whose glass-engaging surfaces are composed of glass-bonded zirconia powder or grains, it has been found that the rate of wear of the walls of the melter increases substantially as the current through the tin oxide electrodes is increased to accommodate higher production rates. This increased wear translates into increased concentrations of dissolved zirconia and increased levels of zirconia-containing solid defects in the finished glass sheets. In addition to the wear problem, when electricity passes through tin oxide electrodes, it generates bubbles at the interface between the electrode and the molten glass. These bubbles represent an additional load on the finer (refiner) used to clarify the molten glass.

In the glass industry, melting effectiveness is often reported in units of square feet/ton/day, where the square feet are the footprint of the melter and the tons/day is the flow rate through the melter. For any designated pull rate (flow rate), the smaller the square feet/ton/day number the better since it means that less square footage will be required in a manufacturing plant to achieve the desired output. For ease of reference, melting effectiveness defined in this way will be referred to herein as the furnace's “Q_{R}-value” given by the formula:

Q_{R}=A_{furnace}/R (1),

where A_{furnace} is the horizontal cross-sectional area of the molten glass in the melting furnace in square feet and R is the rate at which molten glass leaves the furnace and enters the finer in tons of glass per day.

As a consequence of the limitations imposed by current technology, in practice, the maximum flow rates and associated Q_{R}-values for commercial melters to melt display quality glasses have been 1,900 pounds/hour at a Q_{R}-value in the range of 6-7 square feet/ton/day. Above this flow rate, defect levels rise rapidly to unacceptable levels. Although such a flow rate and associated Q_{R}-value is adequate for many applications, melters that are capable of operating at higher flow rates, e.g., at flow rates above 2,000 pounds/hour, without substantial increases in Q_{R}-values are desirable to enable the industry to meet the ever growing demand for large, display quality, glass sheets. Achieving such higher flow rates with Q_{R}-values below 6.0 square feet/ton/day is even more desirable, for example, Q_{R}≤5 square feet/ton/day, Q_{R}≤4.5 square feet/ton/day, Q_{R}≤4 square feet/ton/day, and Q_{R}≤3.5 square feet/ton/day, corresponding to a flow rate, R, of ≥2280, ≥2530, ≥2850 and ≥3260 pounds/hour, respectively.

A low wear rate and thus a low concentration of zirconia and a low level of zirconia-containing solid defects in the finished glass is just one criterion for a successful melting furnace for display quality glass sheets. Other criteria include the ability to achieve high flow rates, ease of fining, compatibility with the agents used to fine (refine) “green” glasses (i.e., glasses that do not contain arsenic or antimony), and low levels of contamination of the display quality glass by the electrode material. The above discussion illustrates just a few examples of challenges faced in the manufacture glass articles, with a specific example related to the manufacture of glass sheets. However, similar problems are faced in a wide variety of apparatus and processes that produce molten glass and then form the molten glass into glass articles, including, but not limited to glass sheets, glass containers, architectural glass, etc.

It would be desirable to provide materials for use in apparatus and methods for producing glass that reduce zirconia concentrations and defect levels.

### SUMMARY

A first aspect of the disclosure pertains to an apparatus for producing a glass article, said apparatus comprising a surface adapted to contact the glass when the glass is in a molten state, at least a portion of the apparatus being composed of or made of zirconia crystal having less than 5% by area glassy phase and having dimensions of at least 1 cm×1 cm on one surface of the block of material. In specific embodiments, the zirconia crystal is a single crystal or polycrystalline. In other specific embodiments, the zirconia crystal is at least one of cubic, tetragonal or monoclinic in structure. In highly specific embodiments, the zirconia crystal is cubic in structure, and in even more specific embodiments, the zirconia crystal is a single crystal and cubic in structure. In some embodiments, the single crystal cubic zirconia does not have any grain boundaries. In some embodiments, the single crystal cubic zirconia is skull method-formed.

A second aspect pertains to an apparatus for producing a glass article, said apparatus comprising a surface adapted to contact the glass when the glass is in a molten state, the surface having a surface area comprising at least 20% of crystal zirconia as the surface and having less than 5% by area glassy phase. In specific embodiments, the zirconia crystal is a single crystal or polycrystalline. In other specific embodiments, the zirconia crystal is at least one of cubic, tetragonal or monoclinic in structure. In highly specific embodiments, the zirconia crystal is cubic in structure, and in even more specific embodiments, the zirconia crystal is a single crystal and cubic in structure. In some embodiments, the single crystal cubic zirconia does not have any grain boundaries. In some embodiments, the single crystal cubic zirconia is skull method-formed.

A third aspect pertains to an apparatus for producing a glass article, said apparatus comprising a surface adapted to contact the glass when the glass is in a molten state, the surface comprising a solid mass of material in the form of a three-dimensional shape comprising a crystal zirconia block of material having less than 5% by area glassy phase and having a mass of at least 12 grams. In specific embodiments, the zirconia crystal is a single crystal or polycrystalline. In other specific embodiments, the zirconia crystal is at least one of cubic, tetragonal or monoclinic in structure. In highly specific embodiments, the zirconia crystal is cubic in structure, and in even more specific embodiments, the zirconia crystal is a single crystal and cubic in structure. In some embodiments, the single crystal cubic zirconia does not have any grain boundaries. In some embodiments, the single crystal cubic zirconia is skull method-formed.

A fourth aspect pertains to a method of making glass article comprising melting batch materials in an apparatus to produce molten glass, the apparatus comprising a surface which contacts molten glass, the surface comprising a block of material made from of a zirconia crystal and having dimensions of at least 1 cm×1 cm. In specific embodiments, the material has a glassy phase content of less than 5%. In specific embodiments, the zirconia crystal is a single crystal or polycrystalline. In other specific embodiments, the zirconia crystal is at least one of cubic, tetragonal or monoclinic in structure. In highly specific embodiments, the zirconia crystal is cubic in structure, and in even more specific embodiments, the zirconia crystal is a single crystal and cubic in structure. In some embodiments, the single crystal cubic zirconia does not have any grain boundaries. In some embodiments, the single crystal cubic zirconia is skull method-formed.

A fifth aspect pertains to a method of making an apparatus for producing a glass article, the method comprising forming a zirconia crystal; and shaping the zirconia crystal into a portion of the apparatus having a surface adapted to contact molten glass, the surface having dimensions of at least 1 cm×1 cm. In specific embodiments, the zirconia crystal is a single crystal or polycrystalline. In other specific embodiments, the zirconia crystal is at least one of cubic, tetragonal or monoclinic in structure. In highly specific embodiments, the zirconia crystal is cubic in structure, and in even more specific embodiments, the zirconia crystal is a single crystal and cubic in structure. In some embodiments, the single crystal cubic zirconia does not have any grain boundaries. In some embodiments, the single crystal cubic zirconia is skull method-formed.

### BRIEF DESCRIPTION OF THE DRAWINGS

The accompanying figures, which are incorporated in and constitute a part of this specification, illustrate several embodiments described below.

FIG. 1 is a schematic drawing illustrating an exemplary apparatus for producing a glass article, in particular, for making flat glass sheets;

FIG. 2 is a perspective view of an exemplary forming apparatus that can be used in the glass manufacturing system of FIG. 2;

FIG. 3 is a cross-sectional side view showing an apparatus according to an embodiment;

FIG. 4 is a cross-sectional side view showing an embodiment of a transfer tube between a first melting furnace and a second melting furnace;

FIG. 5 is a schematic illustration of the cross-section of a fining system according to one embodiment;

FIG. 6 is a schematic perspective drawing, partially in section, of a melting furnace constructed in accordance with the present disclosure; and

FIG. 7 is a graph demonstrating, in logarithmic form, the resistivity of single crystal cubic zirconia over a range of temperatures.

### DETAILED DESCRIPTION

Before describing several exemplary embodiments, it is to be understood that the disclosure is not limited to the details of construction or process steps set forth in the following disclosure. The disclosure provided herein is capable of other embodiments and of being practiced or being carried out in various ways.

In accordance with a first aspect, the disclosure provides materials made of or composed of crystal zirconia for use in glass making equipment. In one or more embodiments “crystal zirconia” refers to a crystalline oxide of zirconium, and in specific embodiments, crystalline ZrO₂. More particularly, in accordance with this aspect, the disclosure provides apparatus (e.g., melting, conditioning, and/or forming apparatus) for producing glass and/or glass articles, said apparatus comprising a surface adapted to or configured to contact the glass when the glass is in a molten state, at least a portion of the surface of the apparatus (e.g., 10-100, 20-100, 30-100, 40-100, 50-100, 60-100, 70-100, 80-100, 90-100, or 95-100 area percent) being composed of a refractory material that comprises zirconia crystal. According to one or more embodiments, as used herein, the phrase “a surface adapted to or configured to contact the glass when the glass is in a molten state” refers to a surface that touches or is in close proximity to the molten glass. For example, in a melting or a fining unit, a tile or brick on a bottom of the melting unit or fining unit may have a surface over which molten glass flows and directly touches a surface of the zirconia crystal material, or molten glass is in close proximity to (e.g., 1-10 cm, 1-5 cm or 1-2 cm) the zirconia crystal material in the apparatus or during practice of the methods claimed herein. In another non-limiting example the area of the melting tank prone to high wear or corrosion including: 1) the wall of the tank closest to where the glass batch is fed into the tank (ordinarily the back wall), and 2) narrowing transition areas that taper from one section in a tank to another section. Thus, “adapted to” or “configured to,” according to one or more embodiments means that the surface has processed or made in a way that is suited to be used as a material in a glass manufacturing apparatus or method in which the glass is in a molten state, for example, as a brick, a tile, an isopipe, or the other components described herein. In specific embodiments, the zirconia crystal is a single crystal cubic zirconia does not have grain boundaries, and is a continuous piece of material, such as a block, a rectangular tile or monolithic piece such as an isopipe or other portion of a glass manufacturing apparatus.

The zirconia crystal refractories of the disclosure can be used to form an entire piece of an apparatus used in a glass manufacturing system or just part of the piece of apparatus. For example, the apparatus, e.g., an isopipe, can have a core and a coating where the coating contacts molten glass and covers all or part of the core, in which case the zirconia crystal refractory of the disclosure can form all or part of the core and/or all or part of the coating. In cases where the zirconia crystal refractory is used as a coating, the core can be a second refractory material. Examples of suitable materials for such a core include, without limitation, alumina, magnesium oxide, a spinel, titanium oxide, yttrium oxide, or a combination thereof. Other refractory materials that can be used for the core include zircon, silicon carbide, xenotime and zirconium oxide. The coating can be applied by standard methods for applying single crystal coatings such as chemical vapor deposition or physical vapor deposition including powdered plasma or flame spray methods. Alternatively, thin tiles (e.g., of zirconia crystal having a thickness less than 10 cm, less than 5 cm, less than 4 cm, less than 3 cm, less than 2 cm, less than 1 cm, less than 0.5 cm, less than 0.4 cm, less than 0.3 cm, less than 0.2 cm or less than 0.1 cm in thickness) can be used to provide a thin “coating” or lining of a bulk article made from a different refractory material and placed in areas of the glass melting furnace which contacts molten glass. These tiles can be formed or machined into shapes capable of physical interlocking (e.g. tongue and groove) where there may be small or no gaps, or may be connected by high temperature grout or cement such as a zirconia-based cement. In one or more embodiments, sides 138′ and 138″ of isopipe 135 shown in FIG. 2 may be lined with crystal zirconia tiles. The tiles can be arranged on the sides 138′ and 138″ of the isopipe such that any gaps between the tiles are not parallel to the direction of flow of the root 216 to eliminate imperfections in the glass sheet. Thus, the tiles can be arranged such that gaps between the tiles are at an angle of 10° to 85° with respect to the direction of the flow of the root 216 shown by the arrows in FIG. 2. In specific embodiments, the gaps between the tiles are on a diagonal with respect the direction of the flow of the root 216 such that the angle between the gaps and the flow direction indicated by the arrows in FIG. 2 is in a range of 30° to 60°, or 40° to 50°.

According to one or more embodiments, the phrases “a portion of the apparatus,” “a portion of said apparatus,” “a portion of an apparatus,” and similar phrases refer to any part of the glass melting system or refers to the entirety of the glass melting system itself. For example, an apparatus may be a melting tank, a fining vessel, a stir chamber, a delivery vessel, a forming structure, connecting tubes or any combination of these. In specific embodiments, “a portion of said apparatus,” “a portion of an apparatus,” and similar phrases may refer a portion of the melting tank such as the portion of the tank surrounding the electrodes, the tapered region of a tank (normally subject to high wear rate or one of the walls (for example the back wall of the tank closest to where the batch materials enter the melter (and subject to higher corrosion than other areas of the tank). When referring to a specific part of the glass melting system such as a melting tank, a fining vessel, a stir chamber, a delivery vessel, a forming structure, connecting tubes, etc., “a portion” can comprise only a part (e.g., 5%, 10%, 15%, 20%, 25%, 30%, 35%, 40%, 45%, 50%, 55%, 60%, 65%, 70%, 75%, 80%, 85%, 90%, 95% (each % by volume)), or the entirety (the whole) of the apparatus according to one or more specific embodiments.

Another embodiment pertains to polycrystalline cubic zirconia bricks and tiles whereby the cubic zirconia bricks are made from cubic zirconia granules (e.g., 0.1 to 5 mm in diameter), then sintered into a solid cubic zirconia object without glass as a bonding agent.

In cases where the zirconia crystal refractory is used as the core, the coating can comprise a second refractory material such as a refractory metal, a spinel, zircon, alumina, or a combination thereof. Examples of suitable refractory metals include platinum, molybdenum, rhodium, rhenium, iridium, osmium, tantalum, tungsten, and alloys thereof.

In addition to their use in isopipes, zirconia crystal refractories can also be used to form all or part of the following components of glass manufacturing equipment which, in typical applications, come into contact with molten glass: pipes, vessels, channels, weirs, bells, stirrers, bricks, blocks, gates, walls, bowls, ladles, needles, sleeves, plugs, molds, rings, plungers, tweels, and the like.

In addition to applications where the zirconia crystal refractory comes into contact with molten glass, zirconia crystal refractories can be used in applications where the refractory does not come into contact with molten glass including: furnace crowns, breast walls, cross walls, and the like. In addition to applications in the glass making industry, the refractories of the disclosure can also be used in other industries where materials that are resistant to high temperatures and/or have high chemical durability are needed. In particular, the refractories of the disclosure can be used in applications where high levels of creep resistance are desirable, although they can be used in other applications where creep resistance is not critical.

Zircon (ZrSiO₄) has been used to produce isopipes, a key component of the fusion draw process for making sheets of display glass. In large part, this choice has been driven by compatibility of the glass with zircon, a criterion of paramount importance as the isopipe and the molten glass are in direct contact with one another at elevated temperatures for a substantial period of time. Defects that might scatter light such as blisters, crystals, etc. are to be held to a minimum.

Zircon's creep resistance at high temperature has also made it a suitable choice for the substrate sizes and glass types used to date in the display industry. However, as discussed above, there has been an ever increasing demand by display manufacturers for larger substrates and glasses with higher performance properties, specifically, glasses with lower susceptibilities to dimensional changes (e.g., compaction) as a result of heating during the display manufacturing process. High strain point glasses can provide the desired dimensional stability. However, because the fusion draw process operates over a narrow viscosity range of ˜10,000 P at the weir to ˜300,000 P at the root, a change to a high strain point glass requires an increase in the operating temperature of the isopipe in order for the high strain point glass to exhibit these viscosity values at the weir and root.

Isopipes made from commercially available zircon are not able to withstand these higher temperatures, while still having practical configurations (practical heights) and use lifetimes. For example, the intrinsic rate of creep for commercially available zircon has been observed to increase by a factor of 28 when going from 1180 to 1250° C. Accordingly, fusion formation of a glass substrate having a strain point that is ˜70° C. higher than current glasses at the same width would require a 5.3 fold increase in the height of the isopipe to maintain even the most minimal of practical lifetimes. In addition to the increase in the rate of creep of zircon, the numbers and size of defects resulting from dissolution of zircon into the glass will increase with temperature. For these reasons, use of a zircon isopipe to fusion form higher strain point glasses is not likely to be practical.

Similarly, even at the temperatures used with current display glasses, commercially available zircon cannot be used to produce wider substrates without substantial decreases in lifetimes and/or substantial increases in heights. As will be evident, the deficiencies of commercially available zircon are even more pronounced in the case of larger substrates made of high strain point glasses. In one or more embodiments, crystal zirconia is used to form a portion of the isopipe.

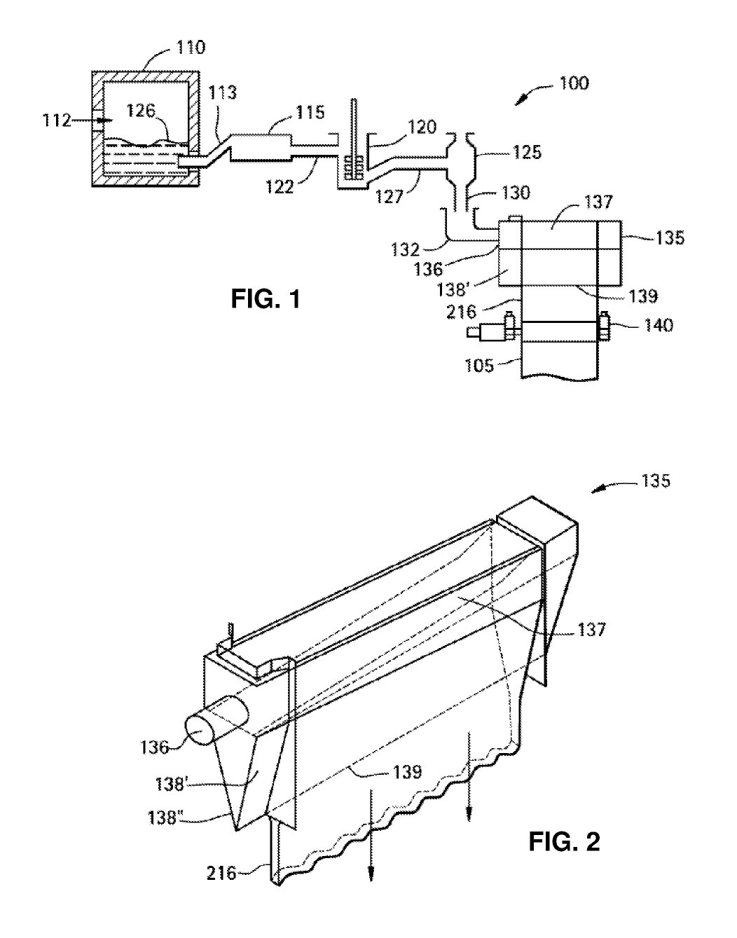

Referring to FIG. 1, there is a diagram of an exemplary glass manufacturing system or apparatus 100 that can use the fusion process to make a glass substrate 105. As shown in FIG. 1, the glass manufacturing system or apparatus 100 includes a melting vessel 110, a fining vessel 115, a mixing vessel 120 (e.g., stir chamber 120), a delivery vessel 125 (e.g., bowl 125), a forming apparatus 135 (e.g., isopipe 135) and a pull roll assembly 140 (e.g., draw machine 140). The melting vessel 110 is where the glass batch materials are introduced as shown by arrow 112 and melted to form molten glass 126. The temperature of the melting vessel (Tm) will vary based on the specific glass composition, but may range from in a range of about 1500°-1650° C. For display glasses for use in liquid crystal displays (LCDs), melting temperatures may exceed 1500° C., 1550° C., and for some glasses, may even exceed 1650° C. A cooling refractory tube 113 may optionally be present connecting the melting vessel with the fining vessel 115. This cooling refractory tube 113 may have a temperature (Tc) that is in a range of about 0°-15° C. cooler than the temperature of the melting vessel 110. The fining vessel 115 (e.g., finer tube 115) has a high temperature processing area that receives the molten glass 126 (not shown) from the melting vessel 110 and in which bubbles are removed from the molten glass 126. The temperature of the fining vessel (Tf) is generally equal to or higher than that of the melting vessel (Tm) in order to lower viscosity and encourage gas removal from the molten glass. In some embodiments, the fining vessel temperature is between 1600° and 1720° C., and in some embodiments exceeds the temperature of the melting vessel by 20° to 70° C., or more. The fining vessel 115 is connected to the mixing vessel 120 (e.g., stir chamber 120) by a finer tube to stir chamber connecting tube 122. Within this connecting tube 122, the glass temperature is continually and steadily decreased from the fining vessel temperature (Tf) to the stir chamber temperature (Ts), which typically represents a temperature decrease of between 150° and 300° C. The mixing vessel 120 is connected to the delivery vessel 125 by a stir chamber to bowl connecting tube 127. The mixing vessel 120 is responsible for homogenizing the glass melt and removing concentration differences within the glass that can cause cord defects. The delivery vessel 125 delivers the molten glass 126 through a downcomer 130 to an inlet 132 and into the forming apparatus 135 (e.g., isopipe 135). The forming apparatus 135 includes a forming apparatus inlet 136 that receives the molten glass which flows into a trough 137 and then overflows and runs down two sides 138′ and 138″ before fusing together at what is known as a root 139 (see FIG. 2). The root 139 is where the two sides 138′ and 138″ come together and where the two overflow walls of molten glass 216 rejoin (e.g., refuse) before being drawn downward between two rolls in the pull roll assembly 140 to form the glass substrate 105.

The various parts of the system or apparatus shown in FIG. 1, for example, the melting vessel 110, the fining vessel 115, the mixing vessel 120, and the delivery vessel 125 and the isopipe 135 can include one or more components that include a surface adapted to or configured to contact molten glass, and the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component.

These components that have a surface configured to or adapted to contact molten glass and used in the manufacture of glass substrates by the fusion process are subjected to extremely high temperature and substantial mechanical loads. To be able to withstand these demanding conditions, according to one or more embodiments, an apparatus for producing a glass includes a surface adapted to contact the glass when the glass is in a molten state is provided, at least a portion of the apparatus being composed of or made of zirconia crystal and having dimensions of at least 1 cm×1 cm on one surface of the block of material. In one or more embodiments, an apparatus for producing a glass is provided, the apparatus including a surface adapted to contact the glass when the glass is in a molten state the surface having a surface area comprising at least 20% of a zirconia crystal as the surface. In one or more embodiments, at least a portion of the apparatus being composed of or made of zirconia crystal and a glassy phase, the glassy phase component of the surface adapted to contact molten glass being less than about 5% of the surface area. In other embodiments, the surface area is substantially free of glassy phase. In one or more embodiments, an apparatus for producing a glass is provided, the apparatus comprising a surface adapted to contact the glass when the glass is in a molten state, the surface comprising a solid mass of material in the form of a three-dimensional shape comprising a zirconia crystal block of material and having a mass of at least 12 grams, at least 120 grams, or at least 1200 grams. In one or more embodiments, at least a portion of the block of material made of a zirconia crystal has a glassy phase component of less than about 5% of the mass. In other embodiments, block is substantially free of glassy phase.

In one or more embodiments, the single crystal zirconia material is highly resistant to wear and generally associated with low inclusion rates in the finished glass substrate product. In one or more embodiments, the single crystal zirconia is in the form or rectangular tiles or blocks created by forming a single crystal block of cubic zirconia from the skull-melting method (which may be referred to herein as “skull-formed”), described in the book Cubic Zirconia and Skull Melting, by Yu S. Kuz'minov, E. E. Lumonova, and V. V. OsikoCambridge International Science Publishing; 2nd edition (Oct. 15, 2008). The single crystal block of cubic zirconia according to one or more embodiments may be stabilized by MgO, CaO, Ce₂O₃, and Y₂O₃ to form the cubic crystal structure. In one or more embodiments, the zirconia crystal comprises at least one of CaO, MgO, Ce₂O₃ or Y₂O₃ at greater than or equal to 1 wt. %. In another embodiment, the zirconia crystal comprises at least one of CaO, MgO, Ce₂O₃ or Y₂O₃ at greater than or equal to 1 wt. % and less than or equal to 40 wt. %. The single crystal cubic zirconia according to one or more embodiments has the following properties: Melting point of 2750° C., Hardness (Mohs) of 8.5, Specific Gravity of 5.95, Refractive Index of 2.17.

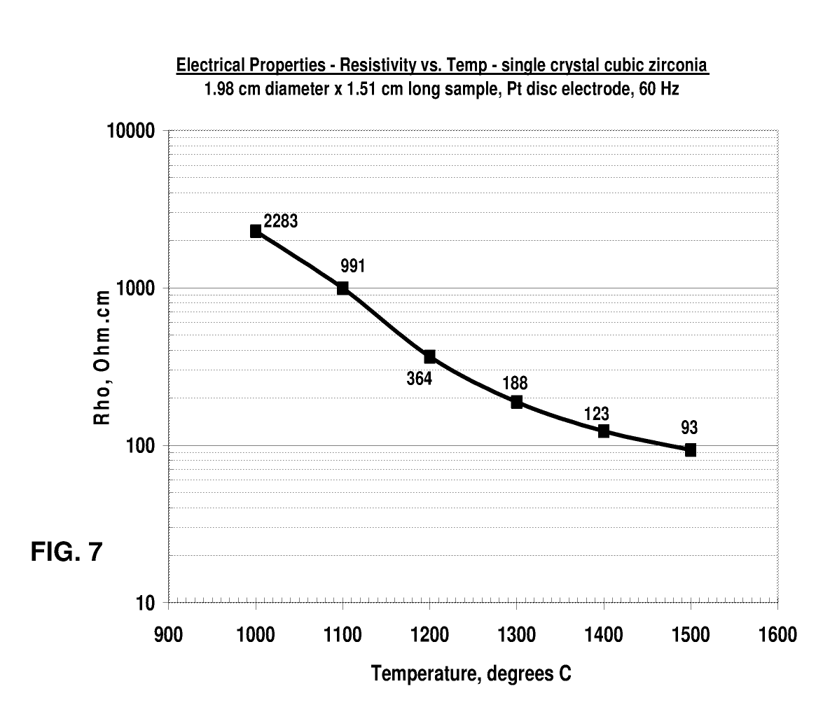

In one or more embodiments, the zirconia crystal provides superior corrosion resistance, providing a longer apparatus life time compared to existing furnace materials that contact molten glass. In an experiment, an exemplary embodiment of single crystal cubic zirconia was analyzed for composition by ICP-OES and by ICP-MS showed the material to be extremely pure: <1 ppm ea. of Li, Na and K; 4 ppm Fe, with the remainder in wt. % as: ZrO₂ (77.2), Y₂O₃ (19.4), HfO₂ (1.6), CaO (1.34), SiO₂ (0.13). Then 1 cm×2.5 cm×0.2 cm weighed coupons of comparative examples of glass-bonded polycrystalline zirconia powder, e.g., electrocast zirconia, (Scimos CZ and Xilec 9 from Saint-Gobain (Courbevoie, France) and an exemplary embodiment of single crystal cubic zirconia (Ceres Crystal Corporation, Niagara Falls, N.Y.), were all placed in separate polypropylene containers containing 49 wt. % HF, and held at 40° C. in a 100 watt ultrasonic bath for 70 minutes. For the Scimos and Xilec samples, within 1 minute there was obvious powder at bottom of polypropylene containers, after 20 minute obvious pitting (˜0.5-1 mm dia.) of the samples, after 70 min these samples were severely pitted and easily crumbled. These comparative samples were then gently rinsed with deionized water, dried at 130° C. for 1 hour and reweighed, the Scimos and Xilec comparative samples lost 10 and 22 wt. % of their initial weight, respectively. In contrast, the single crystal cubic zirconia sample after the same HF exposure appeared unaffected and lost <1 wt. % of its original weight. In one or more embodiments, the cubic zirconia also provides superior resistivity, which allows higher power for electric melting of glass while avoiding the issue fire-through encountered with existing ceramic refractory materials. In an experiment, a portion of this cubic zirconia described above was made into a 1.98 cm diameter×1.51 cm long sample for high temperature electrical resistivity characterization using Pt disc electrodes in contact with the sample ends (diameter). The sample was placed in a temperature controlled furnace and monitored at 60 Hz frequency for resistivity as a function of temperature. The data in FIG. 7 shows the sample of cubic zirconia had excellent resistivity, 1648 Ohm·cm (1000° C.), 797 Ohm·cm (1100° C.), 359 Ohm·cm (1200° C.), 212 Ohm·cm (1300° C.), 157 Ohm·cm (1400° C.) and 194 Ohm·cm (1500° C.) and without being bound by theory, it is believed that the low alkali impurities (<1 ppm total Li, Na, K) is at least partially the reason for excellent resistivity of this cubic zirconia. In one or more embodiments, the cubic zirconia also provides ultra low creep to increase long term furnace performance. In one or more embodiments, the cubic zirconia also provides low reactivity and high temperature ability to be used in place of the current platinum finers and delivery vessels. In one or more embodiments, the cubic zirconia also provides a material with no glassy phase, taking advantage of the high melting temperature of the single crystal material which consists essentially of or consists of crystalline material and no glassy phase. The above-mentioned properties of the cubic zirconia material vary with stabilizers and mole percentage between the zirconia material and the stabilizer.

According to one or more embodiments, an apparatus for producing a glass is provided, the apparatus comprising a surface adapted to contact the glass when the glass is in a molten state, at least a portion of the apparatus being composed of or made of a zirconia crystal and having dimensions of at least ≥1 cm×1 cm, 2 cm×2 cm, 3 cm×3 cm, 4 cm×4 cm or 5 cm×5 cm and larger. According to one or more embodiments, the glassy phase component of the surface adapted to contact molten glass is less than about 5%, 4%, 3%, 2%, 0.5% of the surface area. In other embodiments, the surface area is substantially free of glassy phase. According to one or more embodiments, the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component.

In one or more embodiments an apparatus for producing a glass is provided, the apparatus comprising a surface adapted to contact the glass when the glass is in a molten state, at least a portion of the apparatus being composed of or made of zirconia crystal and a glassy phase, the glassy phase component of the surface adapted to contact molten glass being less than about 5%, 4%, 3%, 2%, 0.5%, 0.25%, 0.1% of the surface area. In other embodiments, the surface area is substantially free of glassy phase. According to one or more embodiments, the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component.

According to one or more embodiments, an apparatus for producing a glass is provided, the apparatus comprising a surface adapted to contact the glass when the glass is in a molten state, at least a portion of the apparatus being composed of or made of zirconia crystal and having at least one single crystal measuring ≥1 cm×1 cm, 2 cm×2 cm, 3 cm×3 cm, 4 cm×4 cm or 5 cm×5 cm and larger. According to one or more embodiments, the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component.

In one or more embodiments an apparatus for producing a glass is provided, the apparatus comprising a surface adapted to contact the glass when the glass is in a molten state, the surface having a surface area comprising at least 20% of a zirconia crystal as the surface. In one or more embodiments, the surface has a surface area comprising at least ≥30%, 40%, 50%, 60%, 70%, 80%, 90%, 95% or 95% of a zirconia crystal as the surface. According to one or more embodiments, the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component.

In one or more embodiments, an apparatus for producing a glass article, said apparatus comprising a surface adapted to contact the glass when the glass is in a molten state is provided, the surface comprising a solid mass of material in the form of a three-dimensional shape comprising a zirconia crystal block of material and having a mass of ≥12 grams (≥120 grams, ≥1200 grams, ≥6000 grams) and having a glassy phase component less than about 5%, 4%, 3%, 2%, 0.5%, 0.25%, 0.1% of the overall mass. In other embodiments, the block of material is substantially free of glassy phase. In one or more embodiments, the block of material does not have any grain boundaries. According to one or more embodiments, the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component. The rectangular tile could be placed in areas of the glass melting furnace which contacts molten glass, and a thin tile (e.g., having a thickness less than 10 cm, less than 5 cm, less than 4 cm, less than 3 cm, less than 2 cm, less than 1 cm, less than 0.5 cm, less than 0.4 cm, less than 0.3 cm, less than 0.2 cm or less than 0.1 cm in thickness) can prevent or reduce thermal shock. The zirconia crystal materials as described herein may also be used in a slot draw that has superior low creep.

It will be understood that while surface of elements described above were described with respect to FIGS. 1 and 2 were with respect to an apparatus or system for manufacturing sheet glass, the present disclosure is not limited to a glass furnace or glass furnace components for making glass sheets, and the discussion above is exemplary only. Thus, glass melting apparatus including furnaces used for other applications such as container glass, architectural glass, automotive glass, and other glass articles could also comprise components made from zirconia crystal.

For example, as mentioned above, platinum is used to manufacture finers and fining vessels in various glass melting operations and apparatus. In one or more embodiments, the zirconia crystal materials described herein could be used to replace components that are typically made from platinum or platinum alloys.

In a conventional glass making process, raw feed materials are heated in a furnace (melter) to form a viscous mass, or glass melt. Furnaces are generally constructed from non-metallic refractory blocks comprised of burned flint clay, sillimanite, zircon or other refractory material. The feed materials may be introduced into the melter either by a batch process, wherein the glass forming constituents are mixed together and introduced into the melter as a discrete load, or the feed materials may be mixed and introduced into the melter continuously. The feed materials may include cullet. The feed materials may be introduced into the melter through an opening or port in the furnace structure, either through the use of a push bar or scoop, in the case of a batch process, or in the case of a continuous feed melter, a screw or auger apparatus may be used. The amount and type of feed material constituents comprises the glass “recipe”. Batch processes are typically used for small amounts of glass and used in furnaces having a capacity on the order of up to a few tons of glass, whereas a large commercial, continuous feed furnace may hold in excess of 1,500 tons of glass, and deliver several hundred tons of glass per day.

The feed materials may be heated in the melter by a fuel-air (or fuel-oxygen) flame issuing from one or more burners above the feed material, by an electric current passed between electrodes typically mounted in the interior melter walls, or both. A crown structure above the walls, also made from refractory block, covers the melter and, in a combustion-heated furnace, provides a space for combustion of the fuel.

In some processes, the feed materials are first heated by a fuel-air flame, whereupon the feed materials begin to melt and the resistivity of the feed materials decreases. An electric current is thereafter passed through the feed materials/melt mixture to complete the heating and melting process. During the heating, reaction of the feed materials releases a variety of gases which form inclusions, commonly referred to as blisters or seeds, within the glass melt. Seeds may also form as a result of air trapped within the interstitial spaces between the particles of feed material, and from dissolution of the refractory blocks themselves into the melt. The gases which may constitute seeds may comprise, for example, any one or a mixture of O₂, CO₂, CO, N₂ and NO. If not removed, seeds may be passed through the glass making process and, undesirably, into the eventual glass product or article (e.g., glass sheet, glass container, etc.). The removal of gaseous inclusions is referred to as fining. Solid inclusions may also make their way into the final product if incomplete melting and dissolution occurs, for example if the melt experiences an insufficient residence time at appropriate temperatures during melting. Solid inclusions which may comprise the melt are unmelted feed materials (stones) and small regions of the glass melt (knots) that have not fully melted and are not homogeneous with the rest of the melt, possessing a refractive index different from the bulk melt.

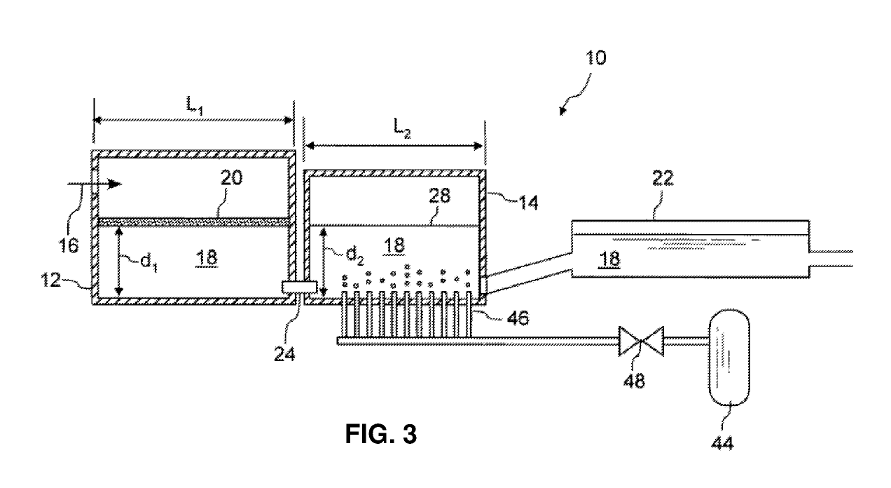

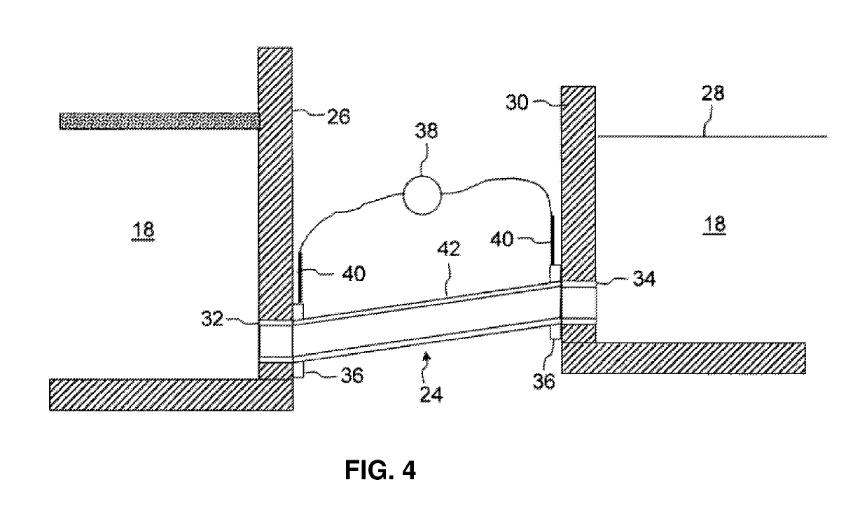

Referring now to FIGS. 3 and 4, in accordance with an embodiment of the present disclosure, a multi-zone melting apparatus is shown, generally indicated by reference numeral 10, comprising a first melting furnace 12 and a second melting furnace 14 separate from the first melting furnace 10. The first and second melting furnaces are generally comprised of refractory blocks as previously disclosed. These refractory blocks can include a surface adapted to contact a surface of molten glass, the surface composed of or made of zirconia crystal, which, in one or more embodiments does not have any grain boundaries. Glass feed materials are fed into first melting furnace 12, as indicated by arrow 16, and are melted to form glass melt 18. The melting process can form a layer of scum or foam 20 on the surface of glass melt 18 within first melting furnace 12, such as in the case of alkali-free aluminosilicate glasses used for display applications. This foam surface layer may comprise both gaseous and solid inclusions, including undissolved feed materials. Melting apparatus 10 may also include fining vessel 22 for removing gaseous inclusions from the glass melt.

First melting furnace 12 is connected to second melting furnace 14 by a connecting tube 24, preferably cylindrical, extending between the first and second melting furnaces. In this context, what is meant by the first furnace being separate from the second furnace is that the furnaces do not share a common wall between the two volumes of glass melt contained in the respective furnaces, and when in operation, the atmospheres in contact with the free (exposed) surface of the two glass melt volumes are not in direct contact with each other.

Connecting tube 24 is typically comprised of a refractory metal which is compatible with the temperature and chemistry of the glass. That is, connecting tube 24 must maintain its structural integrity at temperatures as high as about 1650° C. and produce minimum contamination of the glass. Connecting tube 24 must also be relatively easy to heat in order to increase or maintain the temperature of the molten glass flowing through tube 24. Connecting tube 24 is typically comprised of a refractory metal selected from the platinum group, or alloys thereof. The platinum group metals—ruthenium, rhodium, palladium, osmium, iridium, and platinum—are characterized by resistance to chemical attack, excellent high-temperature characteristics, and stable electrical properties. Other suitable refractory metals include molybdenum. However, according to one or more embodiments of the disclosure, the tube 24 is made from or composed of zirconia crystal, which in some embodiments is a single crystal of cubic zirconia which has no grain boundaries. Tube 24 may be heated, for example by induction heating, namely by flowing a current directly through the tube, or by external heating elements.

As shown in FIGS. 3-4, tube 24 exits first melting furnace 12 through an opening submerged below the surface of glass melt 18 in first melting furnace front wall 26 and enters second melting furnace 14 through a similar opening submerged below surface 28 of glass melt 18 in second melting furnace back wall 30. Thus, as illustrated in FIG. 4, tube 24 includes a first end 32 and a second end 34 opposite first end 32. FIG. 4 shows tube 24 as it exits front wall 26 and enters back wall 30. A portion of tube 24 proximate each end 32, 34 is disposed within the refractory wall of the respective melting furnaces, i.e. a portion of tube 24 is disposed within first melting furnace front wall 26, and a portion of tube 24 is disposed within second melting furnace back wall 30. In the instance where tube 24 is heated by flowing a current through the tube, a flange 36 is attached to tube 24 at front wall 26 and at back wall 30. Flanges 36 serve as electrical contact points for direct resistance heating of tube 24, and may be connected to the power source 38, for example, by buss bars or cables 40. Preferably, flanges 36 are cooled, such as by flowing a liquid (e.g. water) through passages on or in the flanges. Each end 32, 34 is preferably disposed near the mid-point across the width of the respective furnace wall, and further disposed proximate the bottom of the respective furnace. Thus, according to one or more embodiments, with respect to the melting apparatus 10 shown in FIGS. 3-4, any of the following components can include a surface adapted to or configured to contact molten glass and be made from or composed of zirconia crystal, either as an entire part or coated with zirconia crystal: tube 24, front wall 26, back wall 30, cross walls, throats and other surfaces that contact molten glass.

In some embodiments, the second melting surface 14 operates at a significantly increased temperature compared to the first melting surface 12. In such embodiments and due to the increased temperatures, the refractory comprising the glass contact for the second melting surface is much more susceptible to wear. In one embodiment, the second melting surface is adapted to or configured to contact molten glass and be made from or composed of zirconia crystal, either as an entire part or coated with zirconia crystal.

In addition to providing surfaces made from or composed of cubic zirconia in the melter or melting unit as described herein, in one or more embodiments, one or more surfaces in a finer can be made from, composed of, or coated with zirconia crystal, and in specific embodiments, single crystal cubic zirconia that does not have any grain boundaries. Glass as melted from raw materials has many small bubbles of entrapped gases. These bubbles are considered defects in any glass product which requires optical properties. Bubbles of a size that can be seen by the eye or that interfere with the function of the product must be removed. The process for removing these bubbles is termed fining. Fining occurs after the glass is melted from raw materials, but before the glass is formed into a finished product. For optical quality glass this fining process is performed in a “finer” (or refiner), which is constructed of precious metal, typically platinum or a platinum alloy. The fining process is both chemical and physical. Chemicals are added to the glass such that the bubbles grow in size as they pass through the glass melting furnace and the finer. Operating at the highest practical temperature is desirable. This temperature is limited by the high temperature physical properties of the platinum and/or platinum alloy used in the fining apparatus. Structural elements made of platinum, including webs and struts both external and internal, are preferably added to the surfaces of the platinum cylinder to prevent excessive deformation for the expected duration of the production campaign. The highest temperature the glass melt can reach is determined in part by the material of the fining vessel. For example, in a fining system comprising a Pt fining vessel the temperature of the molten glass cannot exceed the melting temperature of Pt. Pure Pt has a melting point of 1768° C. The mechanical integrity of the Pt fining vessel can be seriously compromised if it is heated to a temperature close to its melting point.

Furthermore, platinum is extremely expensive compared to the refractory material and steel required to construct the fining apparatus. The platinum required for the construction of an optical finer can cost in the millions of dollars. Controlling the quantity of platinum used to construct the fining apparatus substantially determines the cost of the fining apparatus. In this disclosure, the criteria for measuring the potential cost is the total surface area of the platinum in contact with the glass. This is the perimeter of the finer times the length of the finer in the configuration where the finer has little or no internal free surface. In the finer configuration with a substantial internal free surface, the area of the top of the finer which is not platinum or platinum clad is subtracted from this calculation.

Different parts of the fining vessel of a fining system may be subjected to differential heating during a fining process, due in part to the differing environment they are exposed to. The lower part of a fining vessel functions as a carrier and holder of molten glass, and thus is in direct contact with the glass. However, the upper part is reserved for gas to escape and thus is typically free from direct contact with the glass melt during the fining step. The differing heat transfer rate of glass and gas can lead to a non-negligible temperature gradient between the top and the side/bottom of the fining vessel. In the present disclosure, the temperature of the top portion is measured at the top of the fining vessel. The temperature at this area tends to have the highest temperature of the fining vessel. The temperature of the side portion of the fining vessel is measured at the side of the fining vessel below the melting glass surface line. This area has a temperature very close to that of the glass melt in direct contact therewith.

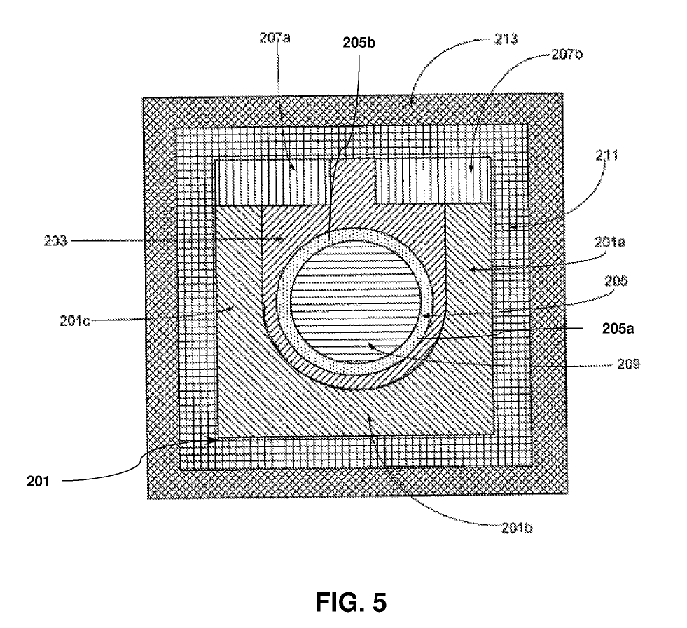

FIG. 5 is a schematic illustration of the cross-section of a fining system or fining apparatus (also referred to as a “finer”) according to one embodiment of the present disclosure, showing a metal vessel 205 in which molten glass 209 is contained and fined. There is shown a first side wall 201a, a base 201b, and a second side wall 201c of a deep cradle 201 containing a fining vessel 205 including a sidewall 205a and a top wall 205b. A bedding material 203 is between the cradle walls and the vessel. Cover plates 207a and 207b cover the vessel 205 and the bedding material. Thermal insulating layers 211 and 213 enclose the cradle 201 and the vessel 205. The thermal insulating layers 211 and 213 may be made of fire boards (such as high temperature-resistant fiber boards made of ceramic fiber). In this embodiment, the use of a deep cradle 201, in addition to the full insulation of the fining vessel, results in minimal heat loss in the fining process and maintains the temperature gradient of the fining vessel within a desired range. However, it will be understood that the claims are not limited to the embodiment shown in FIG. 5. In alternative embodiments, the fining apparatus can be a vacuum fining apparatus, for example, the type shown and described in U.S. Pat. No. 8,484,995.

According to one or more embodiments, fining vessels, finers and components of fining apparatus and systems are provided that can operate in temperature windows that were not heretofore possible with platinum and other refractory metals used to manufacture the fining vessel and the cradle and other components of the fining apparatus or fining system. Thus a fining apparatus or fining system is provided including one or more components such as a cradle and a fining vessel that can operate ≥1675° C., ≥1725° C., ≥1775° C., ≥1800° C., ≥1825° C., ≥1850° C., ≥1875° C., ≥1900° C., ≥1925° C., ≥1950° C., ≥1975° C., ≥2000° C., ≥2100° C., ≥2200° C., and below the melting point of the single crystal cubic zirconia, namely below 2750° C. The ability to operate at such higher temperatures will greatly enhance fining efficiency in glass fining apparatus. The ability to operate at such higher temperatures will also greatly enhance the flow of glass through the glass manufacturing system. For example, Q_{R}≤6 square feet/ton/day, Q_{R}≤5 square feet/ton/day, Q_{R}≤4.5 square feet/ton/day, Q_{R}≤4 square feet/ton/day, and Q_{R}≤3.5 square feet/ton/day, correspond to a flow rate, R, of ≥1900, ≥2280, ≥2530, ≥2850 and ≥3260 pounds/hour, respectively.

Therefore an aspect of the disclosure pertains to a glass making apparatus comprising a fining apparatus comprising a side wall made from a material that is adapted to be in contact with a molten glass during fining of the molten glass, the side wall capable of being exposed to a temperature up to 2750° C. In an embodiment, the side wall is made from zirconia crystal, and in some embodiments, the zirconia crystal is a single crystal of cubic zirconia which does not have grain boundaries.

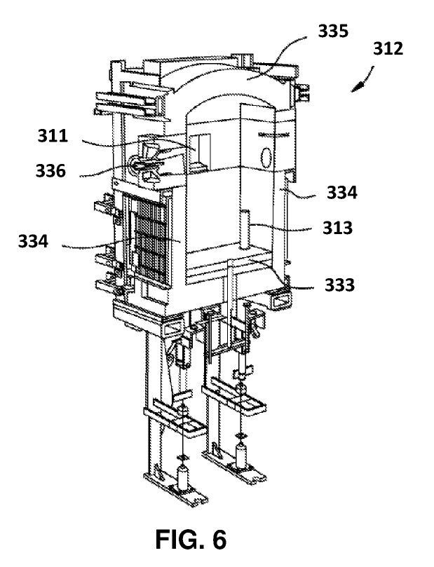

The discussion above with respect to FIGS. 3 and 4 pertains to a multi-zone melting apparatus. According to one or more embodiments, and referring to FIG. 6, the melting apparatus can be a single zone melting apparatus or furnace 312 having a bottom wall 333 and side walls 334 with the electrodes 313 passing through the bottom wall 333 and being spaced from the side walls. In one or more embodiments, the electrodes 313 can pass through the side walls 334 instead of the bottom wall 333. In alternative embodiments, the electrodes 333 can be flush with the walls and not protrude into the furnace. The furnace 312 also includes a crown 335, which as shown in FIG. 6 is curved but may be flat if desired, and burners 336, which may, for example, be gas-oxygen burners. In order to minimize heat loss, in accordance with conventional practice, the walls of the furnace are surrounded by layers of insulating materials (not shown). As discussed above, batch or feed materials to be melted in the furnace to form molten glass may be introduced into the melter or furnace 312 through an opening or port 311 in the furnace structure. According to one or more embodiments, the components of the furnace 312 are composed of or made from a zirconia crystal, and in some embodiments, having no grain boundaries, or the components can be lined with zirconia crystal by a coating or tiles. In specific embodiments, the crown 335, the side walls 334 and the bottom wall 333 can be made from, coated with and/or lined with zirconia crystal. The crown 335, the side walls 334 and the bottom wall 333 can comprise rectangular tiles, bricks or pavers that are monolithic bricks or pavers composed of or made of a continuous piece of single crystal cubic zirconia having no grain boundaries. In specific embodiments of each of the embodiments described herein, the zirconia crystal is a single crystal or polycrystalline. In other specific embodiments, the zirconia crystal is at least one of cubic, tetragonal or monoclinic in structure. In highly specific embodiments, the zirconia crystal is cubic in structure, and in even more specific embodiments, the zirconia crystal is a single crystal and cubic in structure. In some embodiments, the single crystal cubic zirconia does not have any grain boundaries. In some embodiments, the single crystal cubic zirconia is skull method-formed.

Another aspect pertains to a method of making glass comprising fining molten glass in a fining vessel comprising a side wall portion in direct contact with the molten glass, the side wall made from a material that can be exposed to a temperature up to 2750° C. In an embodiment of the method, the side wall is made from a zirconia crystal, and in specific embodiment, the zirconia crystal does not have grain boundaries.

In one or more embodiments, “a single crystal of cubic zirconia” refers to a material that is monocrystalline or made from one single, continuous crystal. In one or more embodiments, “a single crystal of cubic zirconia having no grain boundaries” refers to a material that only has crystalline phase with no other phases, such as glassy phase. In one or more embodiments, In one or more embodiments “zirconia” refers to a crystalline oxide of zirconium, and in specific embodiments, crystalline ZrO₂. A single crystal material is distinguished from a polycrystalline material that is made by ceramic forming methods such as slip casting, dry pressing, and extrusion to provide a formed object, followed by firing of the formed object resulting in material made from multiple smaller crystals (polycrystals). One or more embodiments pertain to polycrystalline cubic zirconia bricks and tiles whereby the cubic zirconia bricks are made from cubic zirconia granules (e.g., 0.1 to 5 mm in diameter), then sintered into a solid cubic zirconia object without glass as a bonding agent. A single crystal or monocrystalline material or solid is a material in which the crystal lattice of the entire object is continuous and unbroken to the edges of the object, with no grain boundaries. According to one or more embodiments, a single crystal of cubic zirconia or a single crystal of cubic zirconia having no grain boundaries is made according to what is known as the skull melting method in a cold crucible, wherein a melt of the material that forms the single crystal is kept in a solid shell (skull), with a chemical composition that is identical to the melt, and a contact-free method of heating (e.g., inductive heating) is used to heat the melt. According to one or more embodiments, the technique allows the melt to be held at very high temperature (up to 3000° C. or higher) to keep it in a stable state for crystallization under controlled conditions.

One or more embodiments of the disclosure provide method of making glass article comprising melting batch materials in an apparatus to produce molten glass, the apparatus comprising a surface which contacts molten glass, the surface comprising a block of material made from of a zirconia crystal and having dimensions of at least 1 cm×1 cm. In one or more embodiments of the method, the glass article is a sheet of display glass. In one or more embodiments of the method, the zirconia crystal is a single crystal is free of voids and defects. In one or more embodiments, the zirconia crystal has a volume % porosity of ≤20%, ≤10%, ≤5%, or ≤1%, ≤0.5%. In one or more embodiments of the method, the single crystal of cubic zirconia contains ≤0.001 or ≤0.0001 wt. % of each alkali selected from Li, Na, and K. In one or more embodiments of the method, the single crystal of cubic zirconia contains ≤0.001 or ≤0.0001 wt. % of all alkali selected from Li, Na, and K. According to one or more embodiments of the method, the surface may be on a front wall, a back wall, a crown, a breast wall, a cross wall, a sidewall, a bottom surface, an inlet, an inlet slot, an exit trough, a ledge, an outlet, a portion of a glass melting vessel, a portion of a fining vessel, a portion of a delivery vessel, a portion of an isopipe, a portion of a furnace cross wall, a furnace throat, an exit block, a back wall block, a glass melting tank, a portion of a rectangular tile, and a portion of a stir chamber component. The rectangular tile could be placed in areas of the glass melting furnace which contacts molten glass, and a thin tile (e.g., having a thickness less than 10 cm, less than 5 cm, less than 4 cm, less than 3 cm, less than 2 cm, less than 1 cm, or less than 0.5 cm in thickness) can prevent or reduce thermal shock. The zirconia crystal materials described herein may also be used in a slot draw arrangement that has superior low creep. The zirconia crystal materials described herein may also be used in updraw arrangement.

Another aspect of the disclosure pertains a method of making an apparatus for producing a glass articles, the method comprising forming a single crystal of cubic zirconia; and shaping the single crystal of cubic zirconia into a portion of the apparatus having a surface adapted to contact molten glass, the surface having dimensions of at least about 1 cm×1 cm, 2 cm×2 cm, 3 cm×3 cm, 4 cm×4 cm or 5 cm×5 cm. According to one or more embodiments, forming the single crystal of cubic zirconia comprises utilizing the skull melting method. In one or more embodiments, the skull melting method utilizes a cold crucible, wherein a melt of the material that forms the single crystal is kept in a solid shell (skull), with a chemical composition that is identical to the melt, and a contact-free method of heating (e.g., inductive heating) is used to heat the melt. According to one or more embodiments, the melt is held at very high temperature (up to 3000° C. or higher) to keep the melt in a stable state for crystallization under controlled conditions. In one or more embodiments, shaping the single crystal comprises shaping the single crystal into a block, a tile or a component such as an isopipe. Shaping may include cutting, sawing, grinding, and/or polishing the single crystal of cubic zirconia.

Various embodiments of the disclosure thus include, but are not limited to, an apparatus for producing a glass article, said apparatus comprising a surface adapted to contact the glass when the glass is in a molten state, the surface comprising at least a portion of the apparatus being made of zirconia crystal having less than 5% by area glassy phase and having dimensions of at least 1 cm×1 cm. In some embodiments, the zirconia crystal is a single crystal or polycrystalline. In some embodiments, the zirconia crystal is at least one of cubic, tetragonal or monoclinic in structure. In some embodiments, the zirconia crystal is cubic in structure. In some embodiments, the zirconia crystal is a single crystal and cubic in structure. In some embodiments, the zirconia crystal comprises at least one of CaO, MgO, Ce₂O₃ or Y₂O₃ at greater than or equal to 1 wt. %. In some embodiments, the zirconia crystal comprises at least one of CaO, MgO, Ce₂O₃ or Y₂O₃ at greater than or equal to 1 wt. % and less than or equal to 40 wt. %. In some embodiments, the crystal is free of voids and defects. In some embodiments, the crystal has ≤20 volume % porosity. In some embodiments, the crystal has ≤10 volume % porosity. In some embodiments, the crystal has ≤5 volume % porosity. In some embodiments, the crystal has ≤1 volume % porosity. In some embodiments, the crystal has ≤0.5 volume % porosity. In some embodiments, the porosity comprises open porosity. In some embodiments, the zirconia crystal contains ≤0.001 wt. % of each alkali selected from Li, Na, and K. In some embodiments, the zirconia crystal contains ≤0.0001 wt. % of each alkali selected from Li, Na, and K. In some embodiments, the zirconia crystal contains ≤0.001 wt. % of total alkali selected from Li, Na, and K. In some embodiments, the zirconia crystal contains ≤0.0001 wt. % of total alkali selected from Li, Na, and K. In some embodiments, the surface is a portion of a glass melting vessel. In some embodiments, the surface is a portion of a fining vessel. In some embodiments, the surface is a portion of a delivery vessel. In some embodiments, the surface is a portion of an isopipe. In some embodiments, the surface is a portion of a furnace cross wall, a furnace throat, an exit block, a back wall block and a glass melting tank. In some embodiments, the surface is a portion of a rectangular tile. In some embodiments, the surface is a portion of a stir chamber component.

In further embodiments an apparatus for producing a glass article is provided, wherein at least a portion of said apparatus comprises a surface adapted to contact the glass when the glass is in a molten state, the at least a portion of said surface having a surface area comprising at least 20% of single crystal cubic zirconia as the surface. In some embodiments, the surface area comprising at least 30%, of a single crystal cubic zirconia as the surface. In some embodiments, the surface area comprising at least 40%, of a single crystal cubic zirconia as the surface. In some embodiments, the surface area comprising at least 50%, of a single crystal cubic zirconia as the surface. In some embodiments, the surface area comprising at least 60%, of a single crystal cubic zirconia as the surface. In some embodiments, the surface area comprising at least 70%, of a single crystal cubic zirconia as the surface. In some embodiments, the surface area comprising at least 80%, of a single crystal cubic zirconia as the surface. In some embodiments, the surface area comprising at least 90%, of a single crystal cubic zirconia as the surface. In some embodiments, the surface area comprising at least 95%, of a single crystal cubic zirconia as the surface. In some embodiments, the surface does not have a grain boundary. In some embodiments, the single crystal cubic zirconia is free of voids and defects. In some embodiments, the single crystal of cubic zirconia contains less than about 0.001 wt. % of alkalis selected from Li, Na, and K. In some embodiments, the surface is a portion of a glass melting vessel. In some embodiments, the surface is a portion of a fining vessel. In some embodiments, the surface is a portion of a delivery vessel. In some embodiments, the surface is a portion of an isopipe. In some embodiments, the surface is a portion of a cross wall, a throat, an exit block, a back wall block and a glass melting tank. In some embodiments, the surface is a portion of a rectangular tile. In some embodiments, the surface is a portion of a stir chamber component.

In additional embodiments an apparatus for producing a glass article is provided, said apparatus comprising a surface adapted to contact the glass when the glass is in a molten state, the surface comprising a solid mass of material in a form of a three-dimensional shape comprising a crystal zirconia block of material and having a mass of ≥12 grams and a glassy phase of less than 5% of the mass of the block. In some embodiments, the apparatus may comprise a crystal zirconia block of material and having a mass of ≥120 grams. In some embodiments, the apparatus may comprise a crystal zirconia block of material and having a mass of ≥1200 grams. In some embodiments, the apparatus may comprise a crystal zirconia block of material and having a mass of ≥6000 grams. In some embodiments, the zirconia crystal is a single crystal or polycrystalline. In some embodiments, the zirconia crystal is at least one of cubic, tetragonal or monoclinic in structure. In some embodiments, the zirconia crystal is cubic in structure. In some embodiments, the zirconia crystal is a single crystal and cubic in structure. In some embodiments, the zirconia crystal comprises at least one of CaO, MgO, Ce₂O₃ or Y₂O₃ at greater than or equal to 1 wt. %. In some embodiments, the zirconia crystal comprises at least one of CaO, MgO, Ce₂O₃ or Y₂O₃ at greater than or equal to 1 wt. % and less than or equal to 40 wt. %. In some embodiments, the crystal is free of voids and defects. In some embodiments, the glassy phase is less than 1%. In some embodiments, the glassy phase is less than 0.5%. In some embodiments, the surface does not have a grain boundary. In some embodiments, the crystal is free of voids and defects. In some embodiments, the crystal has ≤20 volume % porosity. In some embodiments, the crystal has ≤10 volume % porosity. In some embodiments, the crystal has ≤5 volume % porosity. In some embodiments, the crystal has ≤1 volume % porosity. In some embodiments, the crystal has ≤0.5 volume % porosity. In some embodiments, the porosity comprises open porosity. In some embodiments, the crystal of zirconia contains less than about 0.001 wt. % of each alkali selected from Li, Na, and K. In some embodiments, the zirconia crystal contains ≤0.0001 wt. % of each alkali selected from Li, Na, and K In some embodiments, the zirconia crystal contains ≤0.001 wt. % of total alkali selected from Li, Na, and K. In some embodiments, the zirconia crystal contains ≤0.0001 wt. % of total alkali selected from Li, Na, and K. In some embodiments, the surface is a portion of a glass melting vessel. In some embodiments, the surface is a portion of a fining vessel. In some embodiments, the surface is a portion of a delivery vessel. In some embodiments, the surface is a portion of an isopipe. In some embodiments, the surface is a portion of a furnace cross wall, a furnace throat, an exit block, a back wall block and a glass melting tank. In some embodiments, the surface is a portion of a rectangular tile. In some embodiments, the surface is a portion of a stir chamber component.

Further embodiments include a method of making glass article comprising melting batch materials in an apparatus to produce molten glass, the apparatus comprising a surface which contacts molten glass, the surface comprising a block of material made from zirconia crystal having no grain boundaries and having dimensions of at least 1 cm×1 cm. In some embodiments, the zirconia crystal is a single crystal or polycrystalline. In some embodiments, the zirconia crystal is at least one of cubic, tetragonal or monoclinic in structure. In some embodiments, the zirconia crystal is cubic in structure. In some embodiments, the zirconia crystal is a single crystal and cubic in structure. In some embodiments, the zirconia crystal comprises at least one of CaO, MgO, Ce₂O₃ or Y₂O₃ at greater than or equal to 1 wt. %. In some embodiments, the zirconia crystal comprises at least one of CaO, MgO, Ce₂O₃ or Y₂O₃ at greater than or equal to 1 wt. % and less than or equal to 40 wt. %. In some embodiments, the crystal is free of voids and defects.

Additional embodiments include a method of making glass article comprising melting batch materials in an apparatus to produce molten glass, at least a portion of the apparatus comprising a surface which contacts molten glass, the at least a portion of the surface having a surface area comprising at least 20% of a crystal zirconia as the surface. In some embodiments, the zirconia crystal is a single crystal or polycrystalline. In some embodiments, the zirconia crystal is at least one of cubic, tetragonal or monoclinic in structure. In some embodiments, the zirconia crystal is cubic in structure. In some embodiments, the zirconia crystal is a single crystal and cubic in structure. In some embodiments, the zirconia crystal comprises at least one of CaO, MgO, Ce₂O₃ or Y₂O₃ at greater than or equal to 1 wt. %. In some embodiments, the zirconia crystal comprises at least one of CaO, MgO, Ce₂O₃ or Y₂O₃ at greater than or equal to 1 wt. % and less than or equal to 40 wt. %. In some embodiments, the glass article is a sheet of display glass. In some embodiments, the crystal zirconia is free of voids and defects. In some embodiments, the crystal of cubic zirconia contains less than about 0.001 wt. % of alkalis selected from Li, Na, and K. In some embodiments, the surface is a portion of a glass melting vessel. In some embodiments, the surface is a portion of a fining vessel. In some embodiments, the surface is a portion of a delivery vessel. In some embodiments, the surface is a portion of an isopipe. In some embodiments, the surface is a portion of a cross wall, a portion of a throat, a portion of an exit block, a portion of back wall block or a portion of a glass melting tank. In some embodiments, the surface is a portion of a block in a shape of a rectangular tile. In some embodiments, the surface is a portion of a stir chamber component.

Further embodiments include a method of making an apparatus for producing a glass article, the method comprising: forming a crystal of cubic zirconia; and shaping the crystal of cubic zirconia into a portion of the apparatus having a surface adapted to contact molten glass, the surface having dimensions of at least about 1 cm×1 cm. In some embodiments, forming the crystal of cubic zirconia comprises utilizing a skull melting method. In some embodiments, shaping the crystal comprises shaping the single crystal into a block, a tile or a furnace component selected from the group consisting of a portion of a glass melting vessel, a portion of a fining vessel, a portion of a delivery vessel, is a portion of an isopipe, a portion of a cross wall, a portion of a throat, a portion of an exit block, a portion of back wall block, a portion of a glass melting tank, a block in a shape of a rectangular tile, and a portion of a stir chamber component. In some embodiments, shaping comprises one or more of cutting, sawing, grinding, and/or polishing the crystal of cubic zirconia.

Additional embodiments include a glass making apparatus comprising a fining apparatus comprising a side wall made from a material that is adapted to be in contact with a molten glass during fining of the molten glass, the side wall capable of being exposed to a temperature up to 2000° C. In some embodiments, the side wall is made from a crystal of cubic zirconia. In some embodiments, the crystal of cubic zirconia is a single crystal and does not have grain boundaries.

Further embodiments include a method of making glass comprising fining molten glass in a fining vessel comprising a side wall portion in direct contact with the molten glass, the side wall made from a material that can be exposed to a temperature up to 2000° C. In some embodiments, the side wall is made from a crystal of cubic zirconia. In some embodiments, the crystal of cubic zirconia is a single crystal and does not have grain boundaries.

Porosity can be measured according to the Archimedes (density by buoyancy) method. The measurement of surface features such as 5% by area glassy phase, the presence of voids or defects in the materials, the presence of grain boundaries, and percentage surface area of a surface as described herein can be determined by scanning electron microscopy (SEM). The crystalline phase of a material such as cubic, tetragonal or monoclinic can be determined by X-ray diffraction.

While the foregoing is directed to various embodiments, other and further embodiments of the disclosure may be devised without departing from the basic scope thereof, and the scope thereof is determined by the embodiments that follow.

1. Apparatus for producing a glass article, said apparatus comprising a surface adapted to contact the glass when the glass is in a molten state, the surface comprising at least a portion of the apparatus being made of zirconia crystal having less than 5% by area glassy phase and having dimensions of at least 1 cm×1 cm.

2. The apparatus of claim 1, wherein the zirconia crystal is a single crystal or polycrystalline.

3. The apparatus of claim 1, wherein the zirconia crystal is at least one of cubic, tetragonal or monoclinic in structure.

4. The apparatus of claim 1, wherein the zirconia crystal is cubic in structure.

5. The apparatus of claim 1, wherein the zirconia crystal is a single crystal and cubic in structure.

6. The apparatus of claim 1, wherein the zirconia crystal comprises at least one of CaO, MgO, Ce₂O₃ or Y₂O₃ at greater than or equal to 1 wt. %.

7. The apparatus of claim 1, wherein the zirconia crystal comprises at least one of CaO, MgO, Ce₂O₃ or Y₂O₃ at greater than or equal to 1 wt. % and less than or equal to 40 wt. %.

8. The apparatus of claim 1, wherein the crystal is free of voids and defects.

9. The apparatus of claim 1, wherein the crystal has ≤20 volume % porosity.

10. The apparatus of claim 1, wherein the crystal has ≤10 volume % porosity.

11. The apparatus of claim 1, wherein the crystal has ≤5 volume % porosity.

12. The apparatus of claim 1, wherein the crystal has ≤1 volume % porosity.

13. The apparatus of claim 1, wherein the crystal has ≤0.5 volume % porosity.

14. The apparatus of claim 1, wherein the porosity comprises open porosity.

15. The apparatus of claim 1, wherein the zirconia crystal contains ≤0.001 wt. % of each alkali selected from Li, Na, and K.

16. The apparatus of claim 15, wherein the zirconia crystal contains ≤0.0001 wt. % of each alkali selected from Li, Na, and K.

17. The apparatus of claim 15, wherein the zirconia crystal contains ≤0.001 wt. % of total alkali selected from Li, Na, and K.

18. The apparatus of claim 17, wherein the zirconia crystal contains ≤0.0001 wt. % of total alkali selected from Li, Na, and K.

19-111. (canceled)

112. The apparatus of claim 1, wherein the surface is a portion of a glass melting vessel, a fining vessel, a delivery vessel, an isopipe, a furnace cross wall, a furnace throat, an exit block, a back wall block, a glass melting tank, a rectangular tile, or a stir chamber component.

113. Apparatus for producing a glass article, wherein at least a portion of said apparatus comprises a surface adapted to contact the glass when the glass is in a molten state, the at least a portion of said surface having a surface area comprising at least 20% of single crystal cubic zirconia as the surface.

114. The apparatus of claim 113, the surface area comprising between 30% to 100%, of a single crystal cubic zirconia as the surface.

115. The apparatus of claim 113, wherein the surface does not have a grain boundary.

116. The apparatus of claim 113, wherein the single crystal cubic zirconia is free of voids and defects.

117. The apparatus of claim 113, wherein the single crystal of cubic zirconia contains less than about 0.001 wt. % of alkalis selected from Li, Na, and K.

118. The apparatus of claim 113, wherein the surface is a portion of a glass melting vessel, a fining vessel, a delivery vessel, an isopipe, a furnace cross wall, a furnace throat, an exit block, a back wall block, a glass melting tank, a rectangular tile, or a stir chamber component.

119. Apparatus for producing a glass article, said apparatus comprising a surface adapted to contact the glass when the glass is in a molten state, the surface comprising a solid mass of material in a form of a three-dimensional shape comprising a crystal zirconia block of material and having a mass of ≥12 grams and a glassy phase of less than 5% of the mass of the block.

120. The apparatus of claim 119, comprising a crystal zirconia block of material and having a mass of ≥120 grams.

121. The apparatus of claim 119, comprising a crystal zirconia block of material and having a mass of ≥1200 grams.

122. The apparatus of claim 119, comprising a crystal zirconia block of material and having a mass of ≥6000 grams.

123. The apparatus of claim 119, wherein the zirconia crystal is a single crystal or polycrystalline.

124. The apparatus of claim 119, wherein the zirconia crystal is at least one of cubic, tetragonal or monoclinic in structure.

125. The apparatus of claim 119, wherein the zirconia crystal is cubic in structure.

126. The apparatus of claim 119, wherein the zirconia crystal is a single crystal and cubic in structure.

127. The apparatus of claim 119, wherein the zirconia crystal comprises at least one of CaO, MgO, Ce₂O₃ or Y₂O₃ at greater than or equal to 1 wt. %.

128. The apparatus of claim 119, wherein the zirconia crystal comprises at least one of CaO, MgO, Ce₂O₃ or Y₂O₃ at greater than or equal to 1 wt. % and less than or equal to 40 wt. %.

129. The apparatus of claim 119, wherein the crystal is free of voids and defects.

130. The apparatus of claim 119, wherein the glassy phase is less than 1%.

131. The apparatus of claim 119, wherein the glassy phase is less than 0.5%.

132. The apparatus of claim 119, wherein the surface does not have a grain boundary.

133. The apparatus of claim 119, wherein the crystal is free of voids and defects.

134. The apparatus of claim 119, wherein the crystal has ≤20 volume % porosity.

135. The apparatus of claim 119, wherein the crystal has ≤10 volume % porosity.

136. The apparatus of claim 119, wherein the crystal has ≤5 volume % porosity.

137. The apparatus of claim 119, wherein the crystal has ≤1 volume % porosity.

138. The apparatus of claim 119, wherein the crystal has ≤0.5 volume % porosity.

139. The apparatus of claim 119, wherein the porosity comprises open porosity.

140. The apparatus of claim 119, wherein the crystal of zirconia contains less than about 0.001 wt. % of each alkali selected from Li, Na, and K.

141. The apparatus of claim 119, wherein the zirconia crystal contains ≤0.0001 wt. % of each alkali selected from Li, Na, and K.

142. The apparatus of claim 119, wherein the zirconia crystal contains ≤0.001 wt. % of total alkali selected from Li, Na, and K.

143. The apparatus of claim 119, wherein the zirconia crystal contains ≤0.0001 wt. % of total alkali selected from Li, Na, and K.

144. The apparatus of claim 119, wherein the surface is a portion of a glass melting vessel, a fining vessel, a delivery vessel, an isopipe, a furnace cross wall, a furnace throat, an exit block, a back wall block, a glass melting tank, a rectangular tile, or a stir chamber component.

145. A glass making apparatus comprising a fining apparatus comprising a side wall made from a material that is adapted to be in contact with a molten glass during fining of the molten glass, the side wall capable of being exposed to a temperature up to 2000° C.

146. The apparatus of claim 145, wherein the side wall is made from a crystal of cubic zirconia.

147. The apparatus of claim 145, wherein the crystal of cubic zirconia is a single crystal and does not have grain boundaries.
